(19) United States
(12) Patent Application Publication
(10) Pub. No.: US 2025/0321508 A1
(43) Pub. Date: Oct. 16, 2025

(54) LENS REBUILDING SYSTEM AND METHOD OF REBUILDING DAMAGED LENS IN LITHOGRAPHY TOOL

(71) Applicants: TAIWAN SEMICONDUCTOR MANUFACTURING COMPANY, LTD., Hsinchu (TW); TSMC CHINA COMPANY LIMIITED, Shanghai (CN)

(72) Inventors: Xianhui ZHOU, Shanghai City (CN); Lei WANG, Shanghai City (CN); Zihao ZHANG, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/646,502

(22) Filed: Apr. 25, 2024

(30) Foreign Application Priority Data
Apr. 11, 2024 (CN) 202410437920.3

(51) Int. Cl. G03F 7/00; B24B 13/06; G02B 5/00; G02B 27/00; H01J 37/305

(52) U.S. Cl. CPC G03F 7/70975; B24B 13/065; G02B 27/0012; G03F 7/70066; G03F 7/70183; G03F 7/70833; H01J 37/3053; G02B 5/001; H01J 2237/316

(57) ABSTRACT

A method includes removing a damaged lens from a lithography tool; generating an initial profile of a new lens based on a surface profile of the damaged lens; optimizing the initial profile of the new lens by simulating an optical property of the new lens in the lithography tool to generate an optimized profile; fabricating the new lens based on the optimized profile; and mounting the new lens in the lithography tool in place of the damaged lens.

### PRIORITY CLAIM AND CROSS-REFERENCE

This application claims priority to China Application Serial Number 202410437920.3, filed Apr. 11, 2024, which is herein incorporated by reference.

### BACKGROUND

In semiconductor manufacturing, lithography tools are used to apply patterns onto substrates by selectively exposing photoresist layers on the substrates to a radiation beam. Optical lenses are used in a lithography apparatus to direct the radiation beam from a radiation source to the substrate being processed. Optical lenses in lithography tools are made of fine quality materials and need to be replaced regularly because of contamination acquired during operation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography tool in accordance with some embodiments.

FIG. 2 is a schematic view of a damaged lens in accordance with some embodiments.

FIG. 3 is a method of repairing a lens of a lithography tool in accordance with some embodiments.

FIG. 4 is a method of rebuilding a lens based on a damaged lens in accordance with some embodiments.

FIGS. 5A, 5B, and 5C are schematic views of a geometry matrix, a roughness matrix, and a defect matrix in accordance with some embodiments.

FIG. 6 is a method of fabricating a lens in accordance with some embodiments.

FIG. 7 is a schematic view of a focused ion beam (FIB) system in accordance with some embodiments.

FIG. 8 is a block diagram of a lens rebuilding system in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

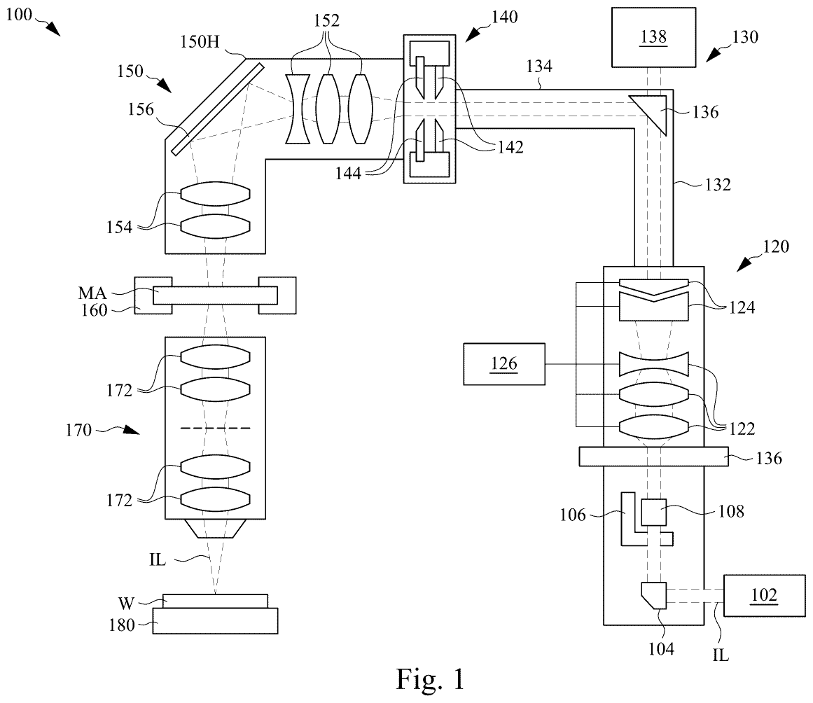

FIG. 1 is a schematic view of a lithography tool in accordance with some embodiments. Shown there is a lithography tool 100. The lithography tool 100 may include an alignment and exposure tool, also known as a stepper and a scanner, configured to transfer circuit design patterns to a light sensitive layer on a substrate. The lithography tool 100 may be an ultra violet (UV) lithography tool, a deep ultra violet (DUV) lithography tool, an immersion lithography tool, an extreme ultra violet (EUV) lithography tool, an electron beam lithography tool, an x-ray lithography tool, an ion projection lithography tool, or any suitable exposure tools using laser radiation source to generate a radiation beam for exposure.

The lithography tool 100 includes a light source 102. In some embodiments, the light source 102 may be an ArF excimer laser light source (oscillation wavelength 193 nm). As the exposure light source, lasers which emit laser light in the ultraviolet range in the oscillation step, such as a KrF excimer laser (wavelength 248 nm) or an F₂ laser (wavelength 157 nm), or devices emitting high-harmonic laser light substantially in the vacuum ultraviolet range, obtained by wavelength conversion of near-infrared laser light from a solid state laser light source (YAG laser, semiconductor laser, or similar), as well as a mercury discharge lamp often used in exposure equipment of this kind, or similar can be used.

In FIG. 1, a radiation beam IL is generated by the light source 102. The radiation beam IL passes through a beam steering system 104. In some embodiments, the beam steering system 104 may include one or more steering mirrors, so as to adjust the propagation direction of the radiation beam IL.

The beam steering system 104 directs the radiation beam IL to a beam-matching unit (BMU) 106, which includes a movable mirror or similar, in order to match the beam to the position of the optical path with the projection exposure apparatus body. A variable attenuator 108 is provided adjacent to the BMU 106. In some embodiments, the variable attenuator 108 is configured to adjust the average energy of each pulse beam of the radiation beam IL. For example, a plurality of optical filters that have different beam attenuating ratios being arranged so that they can be switched to change the beam attenuating ratio in sequence can be used.

The lithography tool 100 further includes a shutter system 110 positioned at the downstream of the BMU 106 and optically coupled with the BMU 106. In some embodiments, the shutter system 110 may include at least one shutter. For example, two shutters are provided to control the output of the radiation beam IL. A safety shutter held open by a coil and arranged to close automatically if any of the panels of a casing of the lithographic apparatus are opened. A rotary shutter is driven by a motor for each exposure.

The lithography tool 100 further includes a zoom-axicon optic system 120 positioned at the downstream of the shutter system 110 and optically coupled with the shutter system 110. The zoom-axicon optic system 120 includes a set of zoom lenses 122 and an axicon 124, which are driven by a motor drive 126. Here, two convex lenses are illustrated as an example of the zoom lenses 122. However, it is understood that this is merely used to explain, it will be appreciated that the zoom lenses 122 may include several lenses, including a combination of convex lenses and/or concave lenses. The zoom lenses 122 are arranged to determine the size of the beam or the outer radius of an annular illumination mode. The set of zoom lenses 122 can be collectively referred to as a zoom lens system.

The axicon 124 includes a concave conical lens and complementary convex conical lens whose separation is adjustable by the motor drive 126. The distance between the two elements of the axicon 124 may be adjusted by moving one of the elements along the direction of the optical axis. This allows the annularity of the radiation beam IL to be adjusted. When the axicon 124 is closed, i.e. the gap between the conical faces is zero, the radiation beam IL may have a disk shape. When a gap is present between the conical faces of the axicon 124, an annular intensity distribution may result, the inner radial extent of the annulus being determined by the distance between the two conical faces.

In the embodiments of FIG. 1, the set of zoom lenses 122 is positioned between the axicon 124 and the light source 102 along the optical path of the radiation beam IL. However, the relative position between the set of zoom lenses 122 and the axicon 124 can be exchanged. For example, in other embodiments, the axicon 124 is positioned between the set of zoom lenses 122 and the light source 102 along the optical path of the radiation beam IL.

The lithography tool 100 further includes an integrator 130 positioned at the downstream of the zoom-axicon optic system 120 and optically coupled to the zoom-axicon optic system 120. In some embodiments, the integrator 130 includes two elongate quartz rods 132 and 134 joined at a right-angle prism 136, the hypotenuse surface of which is partially silvered to allow a small, known proportion of the beam energy through to an energy sensor 138. The radiation beam IL undergoes multiple internal reflections in the quartz rods 132 and 134 so that, looking back through it, there is seen a plurality of spaced apart virtual sources, thus evening out the intensity distribution of the radiation beam IL. The function of the integrator is to improve the homogeneity of the spatial and/or angular intensity distribution of the radiation beam IL.

The lithography tool 100 further includes a reticle blind mechanism 140 at the downstream of the integrator 130 and optically coupled to the integrator 130. In some embodiments, the reticle blind mechanism 140 may include a fixed blind unit 142 and a movable blind unit 144 arranged near the fixed blind unit 142. The fixed blind unit 142 may include blades forming a fixed aperture. The movable blind unit 144 may include movable blades with an adjustable aperture. The arrangement surface of the movable blades that make up the movable blind unit 144 is conjugate to the pattern surface of a reticle (e.g., reticle MA). By using the fixed blind unit 142 and the movable blind unit 144, a slit-shaped illumination area through which a reticle (e.g., reticle MA) is illuminated, can be set at a rectangular shape of a preferred size and form.

The lithography tool 100 further includes a reticle masking (REMA) imaging optic system 150 at the downstream of the reticle blind mechanism 140 and optically coupled to the reticle blind mechanism 140. The REMA imaging optic system 150 includes a housing 150H. In some embodiments, inside the housing 150H, air (oxygen) concentration does not exceed a few percent, and the housing 150H may be filled with clean dry nitrogen gas (N₂), a helium gas (He), and/or other inert gas having an air (oxygen) concentration less than about 1%. The REMA imaging optic system 150 includes a first set of condenser lenses 152 and a second set of condenser lenses 154, in which the first set of condenser lenses 152 and the second set of condenser lenses 154 are optically coupled with each other through a mirror 156. In some embodiments, the first set of condenser lenses 152 may include one or more lenses, and the present disclosure is not limited thereto. Similarly, the second set of condenser lenses 154 may include one or more lenses.

The lithography tool 100 further includes a reticle MA at the downstream of the REMA imaging optic system 150 and optically coupled to the REMA imaging optic system 150. The reticle MA is heled by a reticle stage 160. The radiation beam IL passes through the first set of condenser lenses 152, the mirror 156 to bend the optical path, and the second set of condenser lenses 154, and illuminates an illumination area in the circuit pattern area of the reticle MA. On the reticle stage 160, the reticle MA is fixed, for example, by vacuum chucking. The reticle stage 160 is structured, so that it can be finely driven two-dimensionally within a plane perpendicular to the optical axis of the radiation beam IL to perform positioning of the reticle MA.

The term “reticle” used herein should be broadly interpreted as referring to any device that can be used to impart a radiation beam with a pattern such as to create a pattern in a target portion of the wafer. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit. In some embodiments, the term “reticle” can also be referred to as “mask” or “photomask.”

The lithography tool 100 further includes a projection optic system 170 at the downstream of the reticle MA and optically coupled to the reticle MA. The projection optic system 170 may include a plurality of projection lens 172. The projection optic system 170 projects the radiation beam IL outgoing from the reticle MA onto a wafer W which is coated with a light sensitive material, such as photoresist. In some embodiments, the wafer W is secured on a wafer stage 180 during performing a lithography process.

Along the optical path of the radiation beam IL, the radiation beam IL passes through the beam steering system 104, the BMU 106 (and the variable attenuator 108), the shutter system 110, the zoom-axicon optic system 120, the integrator 130, the reticle blind mechanism 140, the REMA imaging optic system 150, the reticle MA, the projection optic system 170, and is incident on the wafer W. That is, the above mentioned units are optically coupled with each other.

During semiconductor manufacturing, lithography is known as one of the most key process that shrinks and projects the image from a mask (reticle) through projection lens set onto a wafer to form circuit pattern with high density. However, the lenses closest to the optical entrance and the optical exit of the optical system may be exposed to the environment air, will suffer crystallization and contamination after long using time (e.g., 3-5 years) and hence undermine the lens performance such as uniformity, transmission ratio, telecentricity, etc. Since lithography process is highly sensitive to optical behavior, unhealthy lens condition will lead to product low yield or scrap.

In FIG. 1, the optical systems of the lithography tool 100 include the zoom-axicon optic system 120, the REMA imaging optic system 150, and the projection optic system 170. With respect to the zoom-axicon optic system 120, the lenses closest to the optical entrance and the optical exit of the zoom-axicon optic system 120 may be the outmost zoom lens 122 and/or the outmost lens of the axicon 124. For example, the entrance lens of the zoom-axicon optic system 120 may be one of the zoom lenses 122 and the lenses of the axicon 124 closest to the shutter system 110, and the exit lens of the zoom-axicon optic system 120 may be another one of the zoom lenses 122 and the lenses of the axicon 124 closest to the integrator 130. Stated another way, the entrance lens of the zoom-axicon optic system 120 may be the bottommost one of the zoom lenses 122 and the lenses of the axicon 124, and the exit lens of the zoom-axicon optic system 120 may be the topmost one of the zoom lenses 122 and the lenses of the axicon 124.

With respect to the REMA imaging optic system 150, the lenses closest to the optical entrance and the optical exit of the REMA imaging optic system 150 may be the outmost condenser lenses 152 and the out most condenser lenses 154. For example, the entrance lens of the REMA imaging optic system 150 may be one of the condenser lenses 152 closest to the reticle blind mechanism 140, and the exit lens of the REMA imaging optic system 150 may be one of the condenser lenses 154 closest to the reticle MA.

With respect to the projection optic system 170, the lenses closest to the optical entrance and the optical exit of the projection optic system 170 may be the outmost projection lenses 172. For example, the entrance lens of the projection optic system 170 may be one of the projection lenses 172 closest to the reticle MA, and the exit lens of the projection optic system 170 may be one of the projection lenses 172 closest to the wafer W. Stated another way, the entrance lens of the projection optic system 170 may be the topmost one of the projection lenses 172, and the exit lens of the projection optic system 170 may be the bottommost one of the projection lenses 172.

In order to recover lens performance, one way is to clean lens surface with DI water or solvent which may dissolve contaminations, but the method may not be possible to remove insoluble or inner-lens crystallization and moreover, such method would likely to leave mechanical scratch or damage on lens surface due to improper operation. Currently, there is no in-FAB lens repair method for lithography tool due to the complexity of the optical system. For those lenses whose performance is not acceptable, one way is to replace the whole lens set. However, most of the lenses in the lithography tool are aspherical lens, whose cost and manufacturing difficulty are much higher than spherical lens. Even worse, manufacturing of such lens set usually takes lot of time, which makes it hard to replace damaged lens as soon as possible. Another disadvantage of such method is the replacement procedure. After the new lens set arrives at FAB, lithography tool should be disassembled so that the replacement procedure could take place, which takes as long as 50 days to finish hardware installation and machine calibration. Embodiments of the present disclosure provide a method that costs only 1/20 of the old practice, and more important, shorten installation and waiting time for the new lens, which will greatly improve the productivity of FAB.

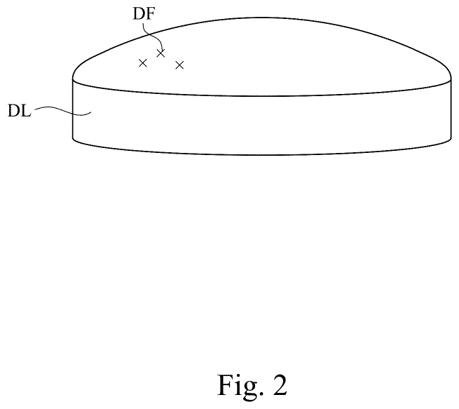

FIG. 2 is a schematic view of a damaged lens in accordance with some embodiments. Shown there is a damaged lens DL. The damaged lens DL can be the entrance and exit lenses of the zoom-axicon optic system 120, the REMA imaging optic system 150, or the projection optic system 170 as described above. The damaged lens DL includes at least one defect DF. The defect DF, for example, can be crystallization, contamination, and/or mechanical damage (e.g., scratch) that can no longer be repaired.

Embodiments of the present disclosure provide a lens rebuild method to make a lens that fit the original optical system. In greater detail, a lens is rebuilt based on the surface profile of the damaged lens (e.g., the damaged lens DL), and the damaged lens of the optical system is replaced with the rebuilt lens. Both time and cost could be saved using such lens rebuild method, which will be discussed in more details later.

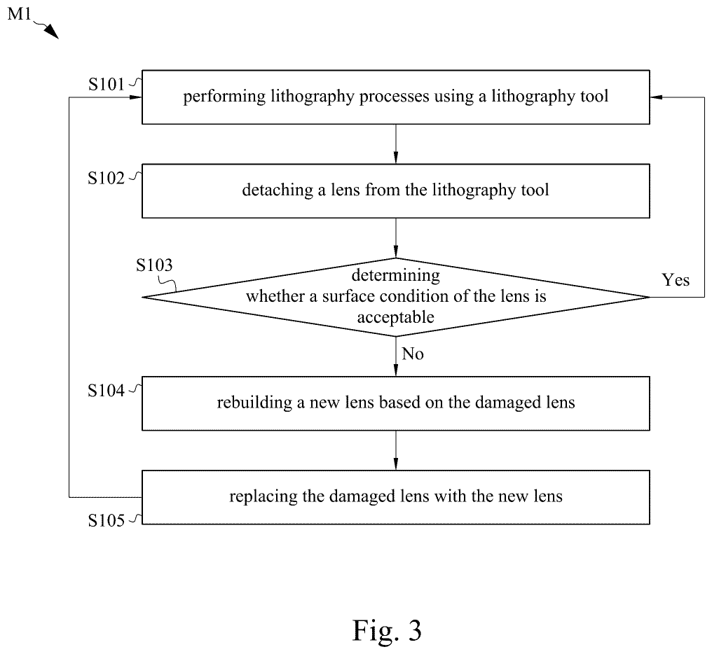

FIG. 3 is a method of repairing a lens of a lithography tool in accordance with some embodiments. A method M1 is provided. Although method M1 is described as a series of acts, it will be appreciated that these acts are not limiting in that the order of the acts can be altered in other embodiments. In other embodiments, some acts that are illustrated and/or described may be omitted in whole or in part.

The method M1 starts from operation S101 by performing lithography processes using a lithography tool. The lithography processes may be performed using the lithography tool 100 as discussed in FIG. 1, and thus relevant details will not be repeated for brevity.

The method M1 proceeds to operation S102 by detaching a lens from the lithography tool. As mentioned above, the lithography process may be performed several times in semiconductor manufacturing. After a long-term use, the entrance and exit lenses of the optical system in the lithography tool 100 may be damaged. Such lens may be detached from the lithography tool 100. The entrance and exit lenses of the optical system in the lithography tool 100 have been described above, and thus relevant details will not be repeated.

The method M1 proceeds to operation S103 by determining whether a surface condition of the lens is acceptable. In some embodiments, a surface cleaning process may first be performed to the lens detached from the lithography tool 100. The surface cleaning process includes using DI water or solvent to remove contamination or particle on the surface of the lens. After the surface cleaning process is complete, the surface condition of the lens is determined.

In some embodiments, the surface condition of the lens is determined as acceptable when the defect of the lens is within a threshold condition. On the other hand, the surface condition of the lens is determined as unacceptable when the defect of the lens is beyond a threshold condition. For example, if the lens includes surface crystallization, surface contamination, and/or surface damage (e.g., scratch) that can no longer be repaired, the surface condition of the lens may be determined as unacceptable.

If the surface condition of the lens is acceptable. The method M1 returns back to operation S101. For example, the lens is mounted back to the lithography tool 100, and lithography processes can be performed using the same lens.

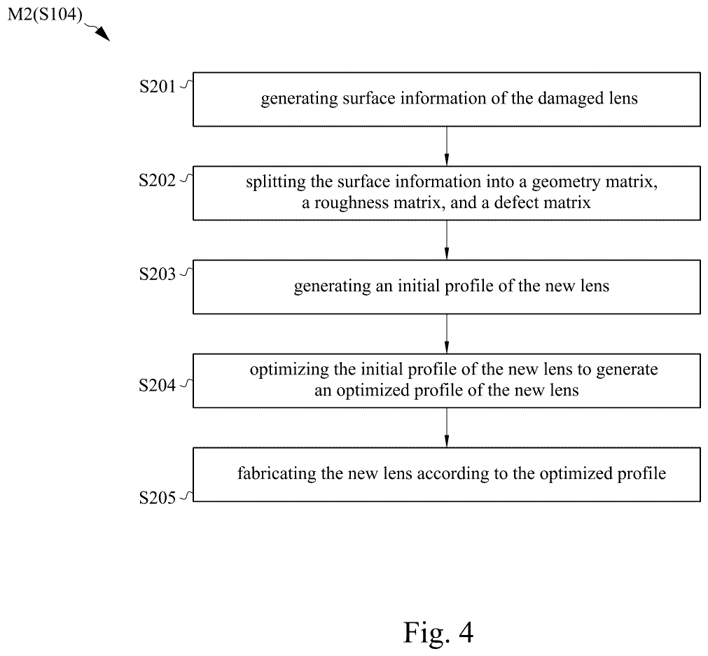

If the surface condition of the lens is unacceptable, the method M1 proceeds to operation S104 by rebuilding a new lens based on the damaged lens. In some embodiments, if the surface condition of the original lens is determined as unacceptable, the original lens can be referred to as a damaged lens. In operation S104, surface information of the damaged lens is detected, and the detected surface information of the damaged lens is used to fabricate a new lens. Details of the operation S104 will be discussed in FIG. 4.

The method M1 proceeds to operation S105 by replacing the damaged lens with the new lens. The new lens is mounted back to the lithography tool 100 in place of the damaged lens. The method M1 then returns back to operation S101. For example, lithography processes can be performed using the new lens. The damaged lens can be discarded. It is noted that only the damaged lens of the lithography tool 100 is replaced with the new lens, while other lenses in the lithography tool 100 remain the same. That is, by using the method, there is no need to replace the whole lens set of the lithography tool 100. Thus, both time and cost could be saved using the lens rebuild method.

FIG. 4 is a method of rebuilding a lens based on a damaged lens in accordance with some embodiments. In greater detail, the method M2 describes the operation S104 in FIG. 3.

The method M2 starts from operation S201 by generating surface information of the damaged lens. To rebuild a damaged lens, a geometrically-desensitized interferometry (GDI) method is used first to precisely measure the surface profile of the damaged lens. A geometrically-desensitized interferometry (GDI) system incorporates a combination of reflecting and refracting optics to perform beam splitting and recombining operations for surface profiling. The precision is controlled at nanometer scale and all retrieved data is record in a matrix. Here, the surface profile matrix includes all information of the surface profile of the damaged lens, such as geometry (e.g., shape), surface roughness, and defects.

The method M2 proceeds to operation S202 by splitting the surface information into a geometry matrix, a roughness matrix, and a defect matrix. In some embodiments, since the measured surface profile contains roughness and defects like crystallization, contamination, and mechanical damage, data processing is necessary to recover the flawless profile. Therefore, a computational process is performed to split the measured data (e.g., the original surface profile matrix) in to three matrices: a geometry matrix, a roughness matrix, and a defect matrix.

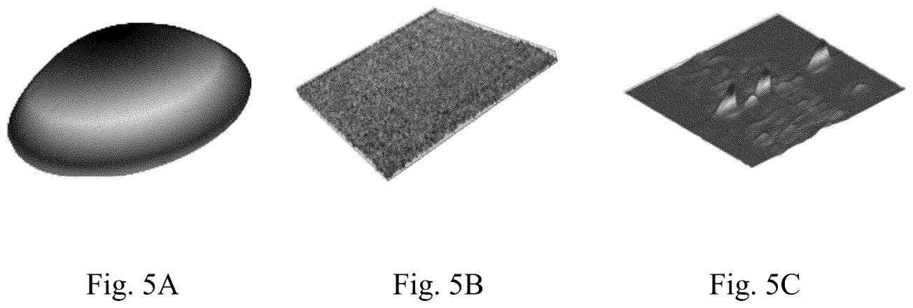

FIGS. 5A, 5B, and 5C are schematic views of a geometry matrix, a roughness matrix, and a defect matrix in accordance with some embodiments. As shown in FIG. 5A, the geometry matrix records the “shape” of the damaged lens. For example, it can be seen that only the shape of the damaged is shown in FIG. 5A, the geometry matrix can be regarded as a perfect profile as it does not include surface roughness and defects. In FIG. 5B, the roughness matrix records the “surface roughness profile” of the damaged lens. For example, it can be seen that the surface topography of the damaged lens is shown in FIG. 5B. In FIG. 5C, the defect matrix records the “defect profile” of the damaged lens. For example, it can be seen that the shape(s) of the defect(s) of the damaged lens is shown in FIG. 5C.

The method M2 proceeds to operation S203 by generating an initial profile of the new lens. In some embodiments, the geometry matrix and the roughness matrix derived from the damaged lens are used as the initial profile of the new lens. That is, the defect matrix is not used as a part of the initial profile of the new lens. Stated another way, the surface profile of the damaged lens without defect(s) is set as an initial profile of the new lens.

The method M2 proceeds to operation S204 by optimizing the initial profile of the new lens to generate an optimized profile of the new lens. In some embodiments, the geometry matrix and the roughness matrix derived from the damaged lens are used as an input to simulate the optical property of the new lens in the lithography tool (e.g., the lithography tool 100). The profile matrix of the new lens (e.g., the combination of the geometry matrix and the roughness matrix) is simulated using finite element analysis to exam the theoretical performance of the new lens. The optimization process also includes iteration process until a desired lens profile of the new lens is obtained. In greater detail, the iteration process includes iteratively revising the parameters of the new lens until the desired lens profile of the new lens is obtained. Here, the parameters of the new lens include the dimension, the radius, the surface accuracy, the air space, the centering of the new lens.

The method M2 proceeds to operation S205 by fabricating the new lens according to the optimized profile. Once the optimized profile of the new lens is generated, the new lens can be fabricated according to the optimized profile. That is, the fabricated new lens may include a profile that is substantially identical to the simulated optimized profile.

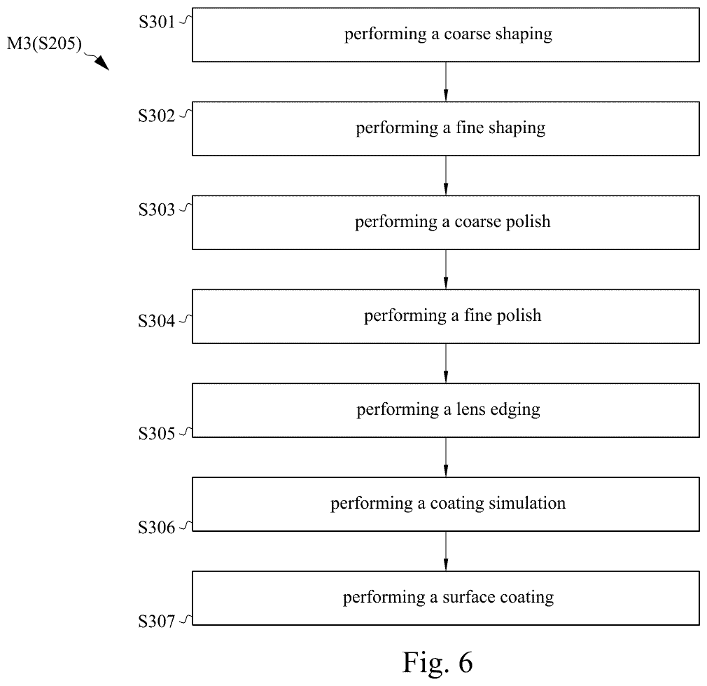

FIG. 6 is a method of fabricating a lens in accordance with some embodiments. In greater detail, the method M3 describes the operation S205 in FIG. 4.

The method M3 starts from operation S301 by performing a coarse shaping. In coarse shaping, a slab of lens material (e.g., glass) is cut with a glass saw to obtain a workpiece.

The method M3 proceeds to operation S302 by performing a fine shaping. After the coarse shaping is complete, a fine shaping is performed to shape the workpiece, such that the workpiece has a desired size and a desired curvature of the surface.

The method M3 proceeds to operation S303 by performing a coarse polish. After the fine shaping is complete, a coarse polish is performed to the workpiece. In some embodiments, the coarse polish may be a contact-type polishing method. For example, a rotating polisher is pressed against the surface of the workpiece with abrasive to polish the surface of the workpiece. That is, during the coarse polish, the polisher may be in contact with the surface of the workpiece.

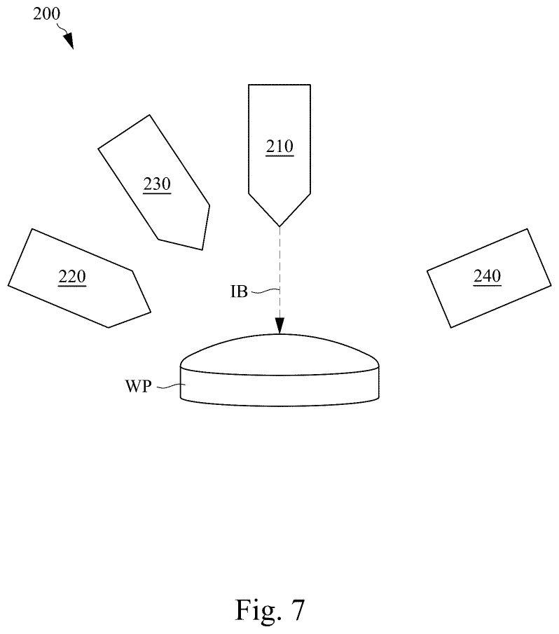

The method M3 proceeds to operation S304 by performing a fine polish. After the coarse polish is complete, a fine polish is performed to the workpiece. In some embodiments, the fine polish may be a noncontact-type polishing method. The fine polish may include using multi-grade focused ion beam (FIB) method. Referring top FIG. 7, shown there is a schematic view of a focused ion beam (FIB) system in accordance with some embodiments. Shown there is a FIB system 200. The FIB system 200 includes a FIB generator 210 configured to produce a focused ion beam IB on a workpiece WP (e.g., the new lens). In some embodiments, the FIB generator 210 may include an ion source, at least one electromagnetic (e.g. electrostatic) lenses and at least one deflector, which collectively serve to produce a focused ion beam. The FIB system 200 further includes a gas injection system (GIS) 220. The GIS 220 is configured to supply a gas over the workpiece WP to enhance a polishing operation performed on the workpiece WP. The FIB system 200 further includes a scanning electron microscope (SEM) 230 producing a beam of electrons toward the workpiece WP, and a detector 240 for detecting secondary or backscattered particles generated from the impact of the ion beam or the electron beam onto the surface of the workpiece WP.

During the fine polish of the workpiece, several polish cycles may be performed on the surface of the workpiece to obtain a required surface roughness. In greater detail, the ion beam energies of the polish cycles may decrease cycle by cycle. That is, the ion beam energy of each polish cycle is lower than the ion beam energy of previous polish cycle. This is because the lower the energy, the better the polish effect and longer polish time. This FIB process is of high flexibility since one can achieve different surface performance by energy control. Also, the method could clean the sub-surface contamination in the workpiece and therefore increase coating quality in the following step. In some embodiments, the FIB process can provide the new lens with even better surface roughness. For example, by using the FIB process for the fine polish step, the surface roughness of the new lens can be lower than the surface roughness of the original lens (e.g., the damaged lens). For example, the root mean square (RMS) roughness of the new lens is lower than the RMS roughness of the original lens (e.g., the damaged lens).

The method M3 proceeds to operation S305 by performing a lens edging. The workpiece undergoes a lens edging such that the final lens can fit into the lithography tool. For example, the lens edging includes grinding the edges of the workpiece with an edging tool such as a grinding wheel until the desired lens shape is reached.

The method M3 proceeds to operation S306 by performing a coating simulation. After the lens edging is complete, the workpiece is going to be coated with several layers. However, the coating usually consists of 20 to 40 layers, and such complexity makes it difficult to achieve same performance as the original lens. Thus, a coating simulation is performed to reverse engineering coating, layer by layer, and to simulate the final coating quality. In greater detail, the coating simulation includes using spectrometer to obtain the optical characteristics of the workpiece (without coating), and the optical characteristics can be used to simulate the optical characteristics of the new lens to generate a simulation result. The simulation result may include the information of the coating layers. Here, the optical characteristics may include diameter, radius of curvature, surface aspheric coefficient, surface accuracy, surface defects, roughness, coating thickness, transmittance, reflectivity, refractivity, etc.

The method M3 proceeds to operation S307 by performing a surface coating. After the coating simulation is complete, the workpiece is coated with coating layers according to the simulation result. In some embodiments, the coating layers may include lanthanide, fluoride, or the like.

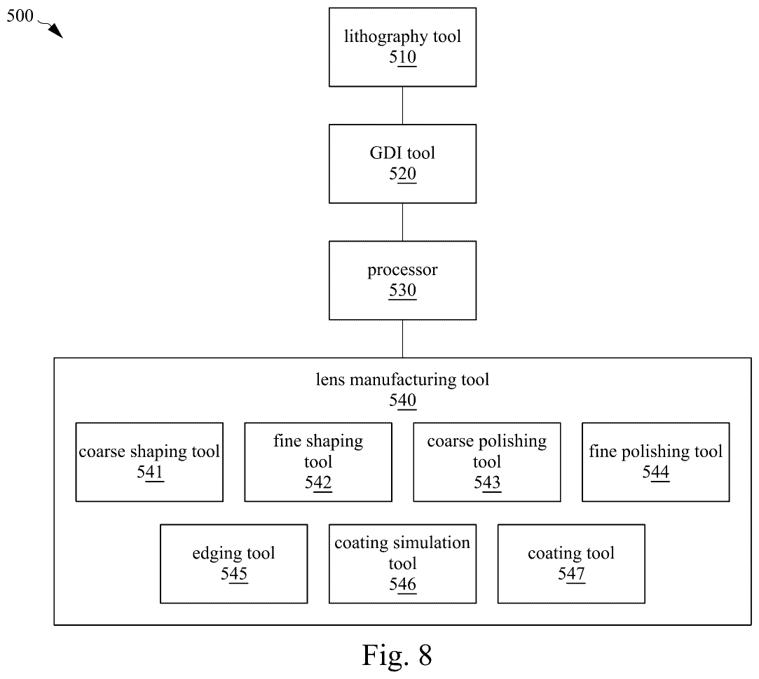

FIG. 8 is a block diagram of a lens rebuilding system in accordance with some embodiments. Shown there is a lens rebuilding system 500. The lens rebuilding system 500 includes a lithography tool 510, a geometrically-desensitized interferometry (GDI) tool 520, a processor 530, and a lens manufacturing tool 540 connected with each other.

The lithography tool 510 may be configured to perform a lithography process. In some embodiments, the lithography tool 510 may be the lithography tool 100 as discussed in FIG. 1.

The GDI tool 520 may be configured to measure a surface profile of a lens, such as the damaged lens as discussed above. In some embodiments, the GDI tool 520 may include an interferometer. The interferometer detects surface topography by comparing the workpiece surface (e.g., the surface of the damaged lens) with a reference surface. The reference surface may be a flat surface or a surface having a known surface topography. The interferometer further includes a wave source, a polarization beam splitter, an imaging module, and an analyzer. The wave source is configured to provide a wave. In some embodiments, the wave may be ultraviolet light, visible light, or infrared light. The polarization beam splitter is configured to split the wave into two polarized waves respectively directed to the workpiece surface and the reference surface. The imaging module is configured to detect an interference wave created by recombining two reflected polarized waves respectively from the workpiece surface and the reference surface. The analyzer is configured to determine the height of the relevant region based on the interference wave.

The processor 530 may be a computer with suitable software to perform the operations S202, S203, and S204 of the method M2 as discussed in FIG. 4. For example, the processor 530 can receive the surface information of a damaged lens from the GDI tool 520. The processor 530 may be configured to split the surface information into a geometry matrix, a roughness matrix, and a defect matrix (e.g., operation S202). The processor 530 is configured to generate an initial profile of a new lens (e.g., operation S203). The processor 530 is configured, using finite element analysis, to exam the theoretical performance of the new lens. The processor 530 is configured, using iteration process, to simulate the theoretical performance of the new lens until a desired lens profile of the new lens is obtained (e.g., operation S204).

The lens manufacturing tool 540 is configured to perform the operation S205 of the method M2 as discussed in FIG. 4. The lens manufacturing tool 540 includes a coarse shaping tool 541, a fine shaping tool 542, a coarse shaping tool 543, a fine shaping tool 544, an edging tool 545, a coating simulation tool 546, and a coating tool 547.

The coarse shaping tool 541 is configured to perform the operation S301 of the method M3 of FIG. 6. In some embodiments, coarse shaping tool 541 may include a glass saw for cutting a slab of lens material (e.g., glass) to obtain a workpiece.

The fine shaping tool 542 is configured to perform the operation S302 of the method M3 of FIG. 6. In some embodiments, the fine shaping tool 542 may include a mold and a heater. For example, the workpiece may be heated using the heater to softness, rolled to a round shape, and pressed in the mold to the desired size and to approximately the desired curvature of the surface.

The coarse polishing tool 543 is configured to perform the operation S303 of the method M3 of FIG. 6. In some embodiments, the coarse polishing tool 543 may include a supporter and rotating polisher. For example, the workpiece is placed on the supporter, and the rotating polisher is pressed against the surface of the workpiece with abrasive to polish the surface of the workpiece.

The fine polishing tool 544 is configured to perform the operation S304 of the method M3 of FIG. 6. In some embodiments, the fine polishing tool 544 may include the FIB tool 200 as discussed in FIG. 7. For example, fine polishing tool 544 is configured to polishing the workpiece using focused ion beam.

The edging tool 545 is configured to perform the operation S305 of the method M3 of FIG. 6. In some embodiments, the edging tool 545 may include an edging tool such as a grinding wheel. For example, the edging tool 545 is configured to grinding the edges of the workpiece.

The coating simulation tool 546 is configured to perform the operation S306 of the method M3 of FIG. 6. In some embodiments, the coating simulation tool 546 may include spectrometer and a computer. For example, the spectrometer is configured to obtain the optical characteristics of the workpiece (without coating), and the computer is configured to simulate the optical characteristics of the new lens.

The coating tool 547 is configured to perform the operation S307 of the method M3 of FIG. 6. In some embodiments, the coating tool 547 may include a supporter and a nozzle. For example, the workpiece is placed on the supporter. The nozzle, which is connected to a coating material tank, is configured to supply coating material, either in liquid form or in gas form, on the surface of the workpiece. The supporter may rotate the workpiece to such that the coating material form a thin film on the surface of the workpiece.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a lens rebuild method to make a lens that fit the original optical system. In greater detail, a lens is rebuilt based on the surface profile of the damaged lens, and the damaged lens of the optical system is replaced with the rebuilt lens. Both time and cost could be saved using such lens rebuild method.

In some embodiments of the present disclosure, a method includes removing a damaged lens from a lithography tool; generating an initial profile of a new lens based on a surface profile of the damaged lens; optimizing the initial profile of the new lens by simulating an optical property of the new lens in the lithography tool to generate an optimized profile; fabricating the new lens based on the optimized profile; and mounting the new lens in the lithography tool in place of the damaged lens.

In some embodiments, the surface profile of the damaged lens is generated using a geometrically-desensitized interferometry method.

In some embodiments, the surface profile of the damaged lens is in a form of a matrix, and the method further comprises splitting the matrix into a geometry matrix, a roughness matrix, and a defect matrix, and wherein the geometry matrix records a shape of the damaged lens, the roughness matrix records a surface roughness profile of the damaged lens and the defect matrix records a defect profile of the damaged lens.

In some embodiments, the initial profile of a new lens is generated based on the geometry matrix and the roughness matrix, and without using the defect matrix.

In some embodiments, optimizing the initial profile of the new lens is performed using finite element analysis to simulate the optical property of the new lens and using an iteration process until a desired lens profile of the new lens is obtained.

In some embodiments, the lithography tool comprises a light source, a zoom-axicon optic system optically coupled to the light source, a reticle masking imaging optic system coupled to the zoom-axicon optic system, a reticle optically coupled to the reticle masking imaging optic system, and a projection optic system optically coupled to the reticle. The damaged lens is a lens closet to an optical entrance of the zoom-axicon optic system or an optical exit of the zoom-axicon optic system, a lens closet to an optical entrance of the reticle masking imaging optic system or an optical exit of the reticle masking imaging optic system, or a lens closet to an optical entrance of the projection optic system or an optical exit of the projection optic system.

In some embodiments, fabricating the new lens based on the optimized profile comprises shaping a workpiece; performing a coarse polish to the workpiece; performing a fine polish to the workpiece using a focused ion beam method; and coating the workpiece.

In some embodiments, the method further includes performing a coating simulation to the workpiece to generate a simulation result, and coating the workpiece is performed based on the simulation result.

In some embodiments of the present disclosure, a method includes removing a damaged lens from a lithography tool; generating a profile of a new lens based on a surface profile of the damaged lens; fabricating the new lens based on the profile, wherein fabricating the new lens comprises shaping a workpiece; performing a coarse polish to the workpiece; performing a fine polish to the workpiece, wherein the fine polish is a noncontact-type polishing method; and coating the workpiece; and mounting the new lens in the lithography tool in place of the damaged lens.

In some embodiments, the fine polish is performed using a focused ion beam method.

In some embodiments, the focused ion beam method comprises a plurality of polish cycles, and an ion beam energy of each polish cycle is lower than an ion beam energy of a previous polish cycle.

In some embodiments, the coarse polish is a contact-type polishing method.

In some embodiments, generating the profile of the new lens based on the surface profile of the damaged lens comprises using a geometrically-desensitized interferometry method to generate the surface profile of the damaged lens; generating an initial profile of the new lens based on the surface profile of the damaged lens; and optimizing the initial profile of the new lens by simulating an optical property of the new lens in the lithography tool to generate an optimized profile as the profile of the new lens.

In some embodiments, the surface profile of the damaged lens is in a form of a matrix, and the method further comprises splitting the matrix into a geometry matrix, a roughness matrix, and a defect matrix, wherein the geometry matrix records a shape of the damaged lens, the roughness matrix records a surface roughness profile of the damaged lens, and the defect matrix records a defect profile of the damaged lens, and wherein the initial profile of a new lens is generated based on the geometry matrix and the roughness matrix, and without using the defect matrix.

In some embodiments, the damaged lens is a lens closest to an optical entrance of an optic system of the lithography tool or an optical exit of the optic system of the lithography tool.

In some embodiments of the present disclosure, a lens rebuilding system includes a processor and a lens manufacturing tool. The processor is configured to generate a profile of a new lens based on a surface profile of a damaged lens. The lens manufacturing tool is configured to fabricate the new lens based on the profile. The lens manufacturing tool comprises coarse polishing tool and a fine polishing tool. The coarse polishing tool is configured to perform a first polishing on a work piece of the new lens using a rotating polisher. The fine polishing tool is configured to perform a second polishing on the work piece of the new lens using focused ion beam.

In some embodiments, the first polishing is a contact-type polishing method, and the second polishing is a noncontact-type polishing method.

In some embodiments, the second polishing comprises a plurality of polish cycles, and an ion beam energy of each polish cycle is lower than an ion beam energy of a previous polish cycle.

In some embodiments, lens rebuilding system further includes an interferometer configured to generate the surface profile of the damaged lens.

In some embodiments, the surface profile of the damaged lens is in a form of a matrix, and the processor is configured to split the matrix into a geometry matrix, a roughness matrix, and a defect matrix, and wherein the geometry matrix records a shape of the damaged lens, the roughness matrix records a surface roughness profile of the damaged lens and the defect matrix records a defect profile of the damaged lens, and wherein the processor generates the profile of the new lens based on the geometry matrix and the roughness matrix, and without using the defect matrix.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
removing a damaged lens from a lithography tool;
generating an initial profile of a new lens based on a surface profile of the damaged lens;
optimizing the initial profile of the new lens by simulating an optical property of the new lens in the lithography tool to generate an optimized profile;
fabricating the new lens based on the optimized profile; and
mounting the new lens in the lithography tool in place of the damaged lens.

2. The method of claim 1, wherein the surface profile of the damaged lens is generated using a geometrically-desensitized interferometry method.

3. The method of claim 2, wherein the surface profile of the damaged lens is in a form of a matrix, and the method further comprises splitting the matrix into a geometry matrix, a roughness matrix, and a defect matrix, and wherein the geometry matrix records a shape of the damaged lens, the roughness matrix records a surface roughness profile of the damaged lens and the defect matrix records a defect profile of the damaged lens.

4. The method of claim 3, wherein the initial profile of a new lens is generated based on the geometry matrix and the roughness matrix, and without using the defect matrix.

5. The method of claim 1, wherein optimizing the initial profile of the new lens is performed using finite element analysis to simulate the optical property of the new lens and using an iteration process until a desired lens profile of the new lens is obtained.

6. The method of claim 1, wherein the lithography tool comprising:
a light source;
a zoom-axicon optic system optically coupled to the light source;
a reticle masking imaging optic system coupled to the zoom-axicon optic system;
a reticle optically coupled to the reticle masking imaging optic system; and
a projection optic system optically coupled to the reticle, and wherein the damaged lens is a lens closet to an optical entrance of the zoom-axicon optic system or an optical exit of the zoom-axicon optic system, a lens closet to an optical entrance of the reticle masking imaging optic system or an optical exit of the reticle masking imaging optic system, or a lens closet to an optical entrance of the projection optic system or an optical exit of the projection optic system.

7. The method of claim 1, wherein fabricating the new lens based on the optimized profile comprises:
shaping a workpiece;
performing a coarse polish to the workpiece;
performing a fine polish to the workpiece using a focused ion beam method; and
coating the workpiece.

8. The method of claim 7, further comprising performing a coating simulation to the workpiece to generate a simulation result, and coating the workpiece is performed based on the simulation result.

9. A method, comprising:
removing a damaged lens from a lithography tool;
generating a profile of a new lens based on a surface profile of the damaged lens;
fabricating the new lens based on the profile, wherein fabricating the new lens comprises:
shaping a workpiece;
performing a coarse polish to the workpiece;
performing a fine polish to the workpiece, wherein the fine polish is a noncontact-type polishing method; and
coating the workpiece; and
mounting the new lens in the lithography tool in place of the damaged lens.

10. The method of claim 9, wherein the fine polish is performed using a focused ion beam method.

11. The method of claim 10, wherein the focused ion beam method comprises a plurality of polish cycles, and an ion beam energy of each polish cycle is lower than an ion beam energy of a previous polish cycle.

12. The method of claim 9, wherein the coarse polish is a contact-type polishing method.

13. The method of claim 9, wherein generating the profile of the new lens based on the surface profile of the damaged lens comprises:
using a geometrically-desensitized interferometry method to generate the surface profile of the damaged lens;
generating an initial profile of the new lens based on the surface profile of the damaged lens; and
optimizing the initial profile of the new lens by simulating an optical property of the new lens in the lithography tool to generate an optimized profile as the profile of the new lens.

14. The method of claim 13, wherein the surface profile of the damaged lens is in a form of a matrix, and the method further comprises splitting the matrix into a geometry matrix, a roughness matrix, and a defect matrix,
wherein the geometry matrix records a shape of the damaged lens, the roughness matrix records a surface roughness profile of the damaged lens, and the defect matrix records a defect profile of the damaged lens, and
wherein the initial profile of a new lens is generated based on the geometry matrix and the roughness matrix, and without using the defect matrix.

15. The method of claim 9, wherein the damaged lens is a lens closest to an optical entrance of an optic system of the lithography tool or an optical exit of the optic system of the lithography tool.

16. A lens rebuilding system, comprising:
a processor configured to generate a profile of a new lens based on a surface profile of a damaged lens; and
a lens manufacturing tool configured to fabricate the new lens based on the profile, wherein the lens manufacturing tool comprises:
a coarse polishing tool configured to perform a first polishing on a work piece of the new lens using a rotating polisher; and
a fine polishing tool configured to perform a second polishing on the work piece of the new lens using focused ion beam.

17. The lens rebuilding system of claim 16, wherein the first polishing is a contact-type polishing method, and the second polishing is a noncontact-type polishing method.

18. The lens rebuilding system of claim 16, wherein the second polishing comprises a plurality of polish cycles, and an ion beam energy of each polish cycle is lower than an ion beam energy of a previous polish cycle.

19. The lens rebuilding system of claim 16, further comprising an interferometer configured to generate the surface profile of the damaged lens.

20. The lens rebuilding system of claim 19, wherein the surface profile of the damaged lens is in a form of a matrix, and the processor is configured to split the matrix into a geometry matrix, a roughness matrix, and a defect matrix, and wherein the geometry matrix records a shape of the damaged lens, the roughness matrix records a surface roughness profile of the damaged lens and the defect matrix records a defect profile of the damaged lens, and wherein the processor generates the profile of the new lens based on the geometry matrix and the roughness matrix, and without using the defect matrix.
